(19) United States
(12) Patent Application Publication
(10) Pub. No.: US 2007/0227697 A1
(43) Pub. Date: Oct. 4, 2007

(54) Heat radiator

(75) Inventor: Takayuki Takahashi, Shiojiri-shi (JP)

Correspondence Address: BACHMAN & LAPOINTE, P.C., 900 CHAPEL STREET, SUITE 1201, NEW HAVEN, CT, 06510, US

(73) Assignee: Dowa Metaltech Co., Ltd.

(21) Appl. No.: 11/729,286

(22) Filed: Mar. 28, 2007

(30) Foreign Application Priority Data
Mar. 30, 2006 (JP) 2006-095141
Mar. 14, 2007 (JP) 2007-064363

(51) Int. Cl. H05K 7/20

(52) U.S. Cl. 165/80.4; 165/170; 361/699

(57) ABSTRACT

A heat radiator 10 includes: a first member 12 which has a recessed portion 12c in one side thereof and which has a large number of substantially circular truncated conical protruding portions 12d formed on the bottom face of the recessed portion 12c; and a second member which is fixed to the first member 12 on the side of the recessed portion 12c for defining an internal cavity and which contacts the tip end face of each of the large number of protruding portions 12d of the first member 12, wherein the first member 12 has a pair of through holes 12e for supplying a coolant into the internal cavity and for discharging the coolant from the internal cavity.

### BACKGROUND OF THE INVENTION

1. Field of the Invention

The present invention generally relates to a heat radiator. More specifically, the invention relates to a heat radiator used for radiating heat from a heating element to a coolant which flows therein.

2. Description of the Prior Art

In a conventional metal/ceramic bonding substrate used as an insulating substrate for power modules, a metal circuit plate is bonded to one side of a ceramic substrate, and a radiating metal base plate is bonded to the other side thereof, semiconductor chips and so forth being mounted on the metal circuit plate. In order to radiate heat from heating elements, such as semiconductor chips, to the outside, there is known a method for mounting a radiating fin on the reverse of a radiating base plate via a radiating grease. There is also known a method for bonding a radiating fin to a semiconductor device mounting substrate via a brazing filler metal (see, e.g., Japanese Patent Laid-Open No. 4-363052).

However, since an air-cooling fin is used in the method disclosed in Japanese Patent Laid-Open No. 4-363052, there are problems in that the cooling power of the air-cooling fin is generally lower than that of a water-cooling device and that it is difficult to stabilize the performance of the air-cooling fin.

There are proposed various water-cooling heat radiators for radiating heat from a heating element to a coolant, such as water (see, e.g., Japanese Patent Laid-Open Nos. 62-52945, 1-63142 and 2004-247684).

However, in recent years, the heating values of insulating substrates for power modules are increased by the increase in power and packaging density of semiconductor chips and so forth. Therefore, even if the water-cooling heat radiators proposed in Japanese Patent Laid-Open Nos. 62-52945, 1-63142 and 2004-247684 are used, it is not possible to fully radiate heat from semiconductor chips and so forth unless the structure of the water-cooling heat radiators is complicated and/or unless the size of the water-cooling heat radiators is increased.

### SUMMARY OF THE INVENTION

It is therefore an object of the present invention to eliminate the aforementioned problems and to provide a heat radiator having a high cooling power with a simple structure without increasing the size of a conventional typical heat radiator.

In order to accomplish the aforementioned and other objects, the inventors have diligently studied and found that it is possible to produce a heat radiator having a high cooling power with a simple structure without increasing the size of a conventional typical heat radiator, if an internal cavity communicated with the outside via a through hole is formed in a metal body and if a large number of pillar portions (or columnar portions) extending between the facing two surfaces of the inside surfaces of the internal cavity are provided at intervals. Thus, the inventors have made the present invention.

According one aspect of the present invention, a heat radiator comprises: a metal body having an internal cavity which is formed therein and which has facing two inside surfaces, the metal body having a through hole for establishing a communication between the internal cavity and the outside; and a large number of pillar portions which extend between the facing two inside surfaces and which are arranged at intervals. In this heat radiator, the metal body preferably comprises: a first member having the large number of pillar portions which are integrated therewith; and a second member which is fixed to the first member for defining the internal cavity. Alternatively, the metal body preferably comprises: a first member which has a recessed portion in one side thereof and which has the large number of pillar portions integrated with a bottom face of the recessed portion; and a second member which contacts a tip end of each of the large number of pillar portions of the first member. Each of the large number of pillar portions preferably has a shape of substantially circular truncated cone, substantially circular cone or substantially rectangular parallelepiped. The metal body is preferably made of aluminum or an aluminum alloy.

According to another aspect of the present invention, there is provided a metal/ceramic bonding substrate with heat radiator, which comprises: a ceramic substrate; and a metal circuit plate bonded to one side of the ceramic substrate, wherein the above described heat radiator is bonded to the other side of the ceramic substrate.

According to the present invention, an internal cavity communicated with the outside via a through hole is formed in a metal body, and a large number of pillar portions (or columnar portions) extending between the facing two surfaces of the inside surfaces of the internal cavity are provided at intervals, so that it is possible to produce a heat radiator having a high cooling power with a simple structure without increasing the size of a conventional typical heat radiator.

### BRIEF DESCRIPTION OF THE DRAWINGS

The present invention will be understood more fully from the detailed description given here below and from the accompanying drawings of the preferred embodiments of the invention. However, the drawings are not intended to imply limitation of the invention to a specific embodiment, but are for explanation and understanding only.

In the drawings:

FIG. 1 is a plan view of the first preferred embodiment of a heat radiator according to the present invention;

FIG. 2 is a bottom view of a radiating member of the heat radiator of FIG. 1 before a lid member is mounted on the radiating member;

FIG. 3 is a sectional view of the radiating member of the heat radiator taken along line III-III of FIG. 1 before a lid member is mounted on the radiating member;

FIG. 4 is a sectional view of the heat radiator of FIG. 1 when a lid member is mounted on the radiating member;

FIG. 5 is a bottom view of a radiating member of the second preferred embodiment of a heat radiator according to the present invention;

FIG. 6 is a bottom view of a first modified example of a radiating member of the first preferred embodiment of a heat radiator according to the present invention;

FIG. 7 is a sectional view of the radiating member of FIG. 6;

FIG. 8 is a bottom view of a second modified example of a radiating member of the first preferred embodiment of a heat radiator according to the present invention;

FIG. 9 is a sectional view of the radiating member of FIG. 8;

FIG. 10 is a sectional view of a third modified example of the first preferred embodiment of a heat radiator according to the present invention;

FIG. 11 is a sectional view of a fourth modified example of the first preferred embodiment of a heat radiator according to the present invention;

FIG. 12 is a plan view of the heat radiator of FIG. 11;

FIG. 13 is a sectional view of a fifth modified example of the first preferred embodiment of a heat radiator according to the present invention;

FIG. 14 is a sectional view of a sixth modified example of the first preferred embodiment of a heat radiator according to the present invention;

FIG. 15 is a sectional view of a seventh modified example of the first preferred embodiment of a heat radiator according to the present invention;

FIG. 16 is a sectional view of a mold used for producing a radiating member in the fourth through seventh modified examples of the first preferred embodiment of a heat radiator according to the present invention; and

FIG. 17 is a sectional view of a mold used for producing a lid member in the fourth modified example of the first preferred embodiment of a heat radiator according to the present invention.

### DESCRIPTION OF THE PREFERRED EMBODIMENTS

Referring now to the accompanying drawings, the preferred embodiments of a heat radiator according to the present invention will be described below in detail.

### First Preferred Embodiment

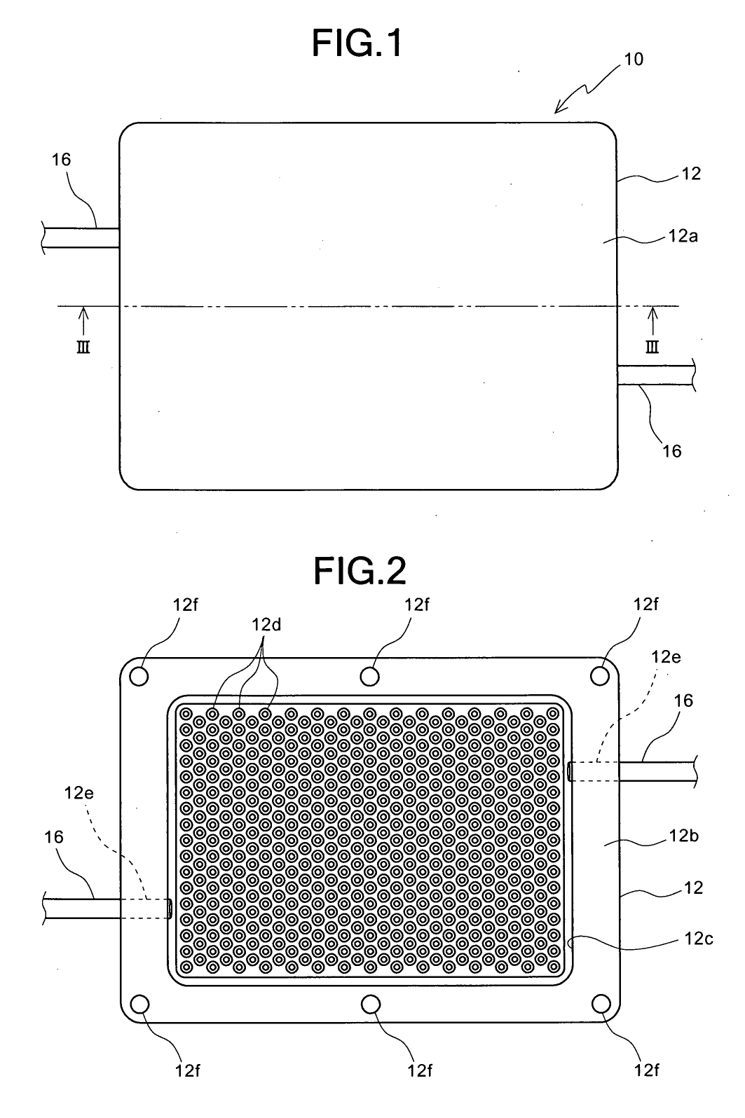

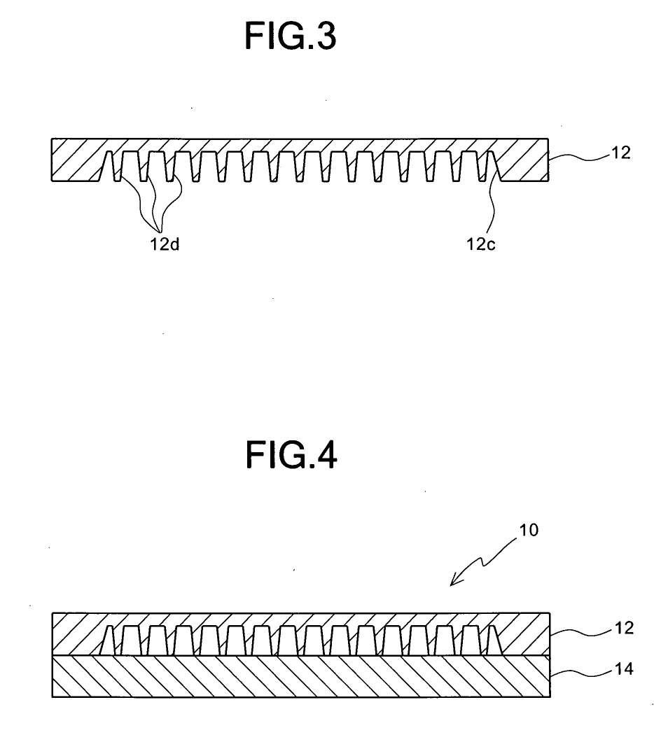

FIGS. 1 through 4 show the first preferred embodiment of a heat radiator according to the present invention. FIG. 1 is a plan view of a heat radiator in this preferred embodiment, and FIG. 2 is a bottom view of a radiating member of the heat radiator of FIG. 1 before a lid member is mounted on the radiating member. FIG. 3 is a sectional view of the radiating member of the heat radiator taken along line III-III of FIG. 1 before a lid member is mounted on the radiating member, and FIG. 4 is a sectional view of the heat radiator of FIG. 1 when a lid member is mounted on the radiating member.

As shown in these figures, the heat radiator 10 in this preferred embodiment comprises: a flat-plate-shaped radiating member (first member) 12 of a metal, such as aluminum or an aluminum alloy, the planar shape of which is a substantially rectangular shape; and a flat-plate-shaped lid member (second member) 14 of a metal, such as aluminum or an aluminum alloy, the planar shape of which is a substantially rectangular shape, the lid member 14 being mounted on the radiating member 12. A pair of tubular members 16 are communicated with an internal cavity which is formed in the heat radiator 10 if the lid member 14 is mounted on the radiating member 12.

As shown in FIG. 1, the top face 12a of the radiating member 12 is flat. The top face 12a is designed to mount thereon a part required for radiating heat from a heating element to a coolant, such as a metal/ceramic bonding substrate on which semiconductor chips and so fourth are mounted. As shown in FIGS. 2 and 3, a substantially rectangular recessed portion 12c is formed in a substantially central portion of the reverse 12b of the radiating member 12.

The bottom face of the recessed portion 12c has a large number of protruding portions (or pillar or columnar protruding portions) 12d, each of which has a shape of substantially circular truncated cone (a shape obtained by cutting the upper end portion of a substantially circular cone in directions substantially parallel to the bottom face). The protruding portions 12d extend to the same height as that of the peripheral portion, which surrounds the recessed portion 12c of the reverse 12b, in directions substantially perpendicular to the top face 12a and reverse 12b of the radiating member 12. The protruding portions 12d are arranged as a plurality of rows of protruding portions 12d. In each row, the protruding portions 12d are arranged at regular intervals. Each row of the protruding portions 12d linearly extends, and the rows of the protruding portions 12d are arranged in parallel to each other. Adjacent two rows of the protruding portions 12d are arranged so as to be shifted from each other at a half pitch (by half of a distance between the central lines (axes of the protruding portions 12d) of adjacent two rows of the protruding portions 12d). The larger number of protruding portions 12d are arranged so as to ensure the distance between the adjacent two of the protruding portions 12d. In this preferred embodiment, for example, each of the protruding portions 12d has a height of about 2 to 50 mm, and preferably has a height of about 5 to 15 mm. The protruding portions 12d are arranged at intervals of about 2 to 10 mm, and preferably at intervals of about 3 to 7 mm. Each of the protruding portions 12d has a tapered angle of 2 to 15°, and preferably a tapered angle of 5 to 10°

A pair of substantially cylindrical through holes 12e pass through the peripheral portion of the radiating member 12 from the side face of the radiating member 12 to the side face of the recessed portion 12c. One of the pair of through holes 12e is formed near a corner portion on one end side in longitudinal directions of the radiating member 12, and the other through hole 12e is formed near the opposite corner portion on the other end side in longitudinal directions of the radiating member 12. The pair of tubular members 16 for feeding a coolant into the recessed portion 12c and for discharging the coolant from the recessed portion 12c are designed to be fitted into the through holes 12e to be mounted thereon.

In the peripheral portion of the reverse 12b of the radiating member 12, six tapped holes 12f are formed. In addition, six tapped holes (not shown) pass through the lid member 14 so as to correspond to the tapped holes 12f. If screws are fitted into the six tapped holes of the lid member 14 which is caused to face the six tapped holes 12f of the radiating member 12, the lid member 14 can be fixed to the radiating member 12 as shown in FIG. 4. If the lid member 14 is thus fixed to the radiating member 12, an internal cavity for housing therein a coolant is formed in the heat radiator 10. Then, the tubular members 16 are mounted in the through holes 12e of the radiating member 12 to complete the heat radiator 10 which is capable of supplying and discharging a coolant via the tubular members 16. Furthermore, the large number of protruding portions 12d are formed in the internal cavity which is formed in the heat radiator 10 by fixing the lid member 14 to the radiating member 12, and flow passages for the coolant are formed between the tubular protruding portions 12d.

Thus, the heat radiator 10 in this preferred embodiment can remarkably increase the area (radiating area) of the internal surface of the heat radiator 10 contacting the coolant to greatly enhance the cooling power of the heat radiator 10 by forming the large number of protruding portions 12d in the internal cavity in which the coolant flows.

### Second Preferred Embodiment

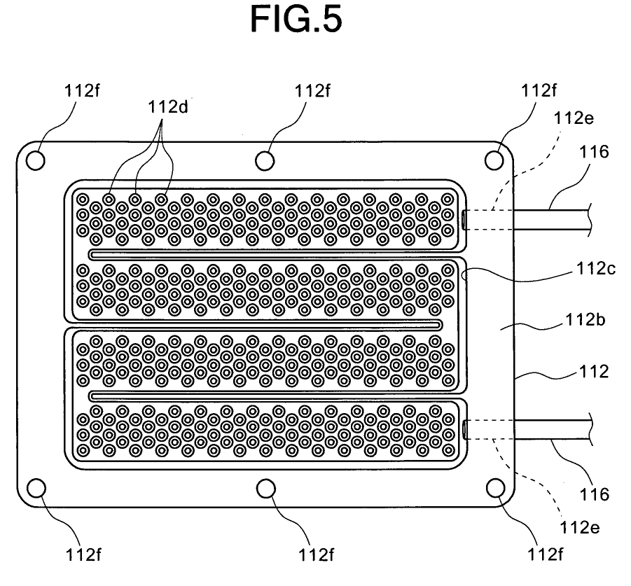

FIG. 5 shows the reverse of a radiating member of the second preferred embodiment of a heat radiator according to the present invention. The heat radiator in this preferred embodiment substantially has the same construction as that of the heat radiator 10 in the first preferred embodiment, except that a tortuously extending (or meandering or snaking) recessed portion 112c is formed by connecting four recessed portions, which extend in parallel to each other in longitudinal directions, in place of the substantially rectangular recessed portion 12c of the radiator 10 in the first preferred embodiment, and that a pair of through holes 112e pass through the peripheral portion of the radiating member 112 from both ends of the recessed portion 112c to the side face of the radiating member 112. Therefore, reference numbers in FIG. 5 are shown by adding 100 to the reference numbers given to the same structural portions as those of the heat radiator 10 in the first preferred embodiment, and the duplicate descriptions thereof are omitted.

Thus, the heat radiator in this preferred embodiment can also remarkably increase the area (radiating area) of the internal surface of the heat radiator contacting the coolant to greatly enhance the cooling power of the heat radiator by forming the large number of protruding portions 112d in the internal cavity in which the coolant flows. In addition, the cooling power of the heat radiator in this preferred embodiment can be higher than that of the heat radiator 10 in the first preferred embodiment, since the recessed portion 112c tortuously extends for allowing the flow of a coolant.

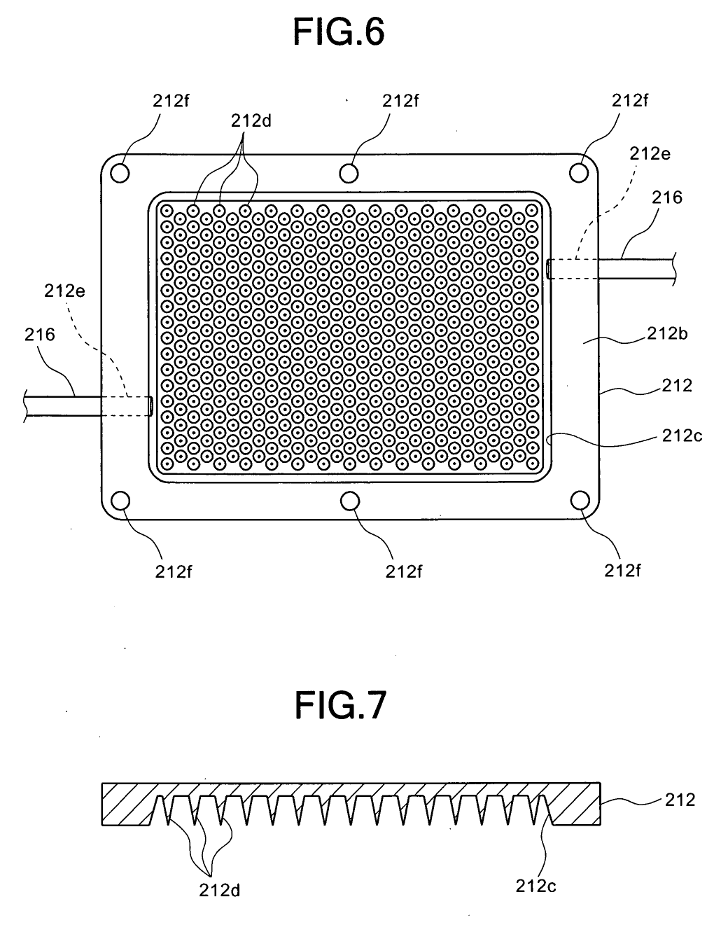

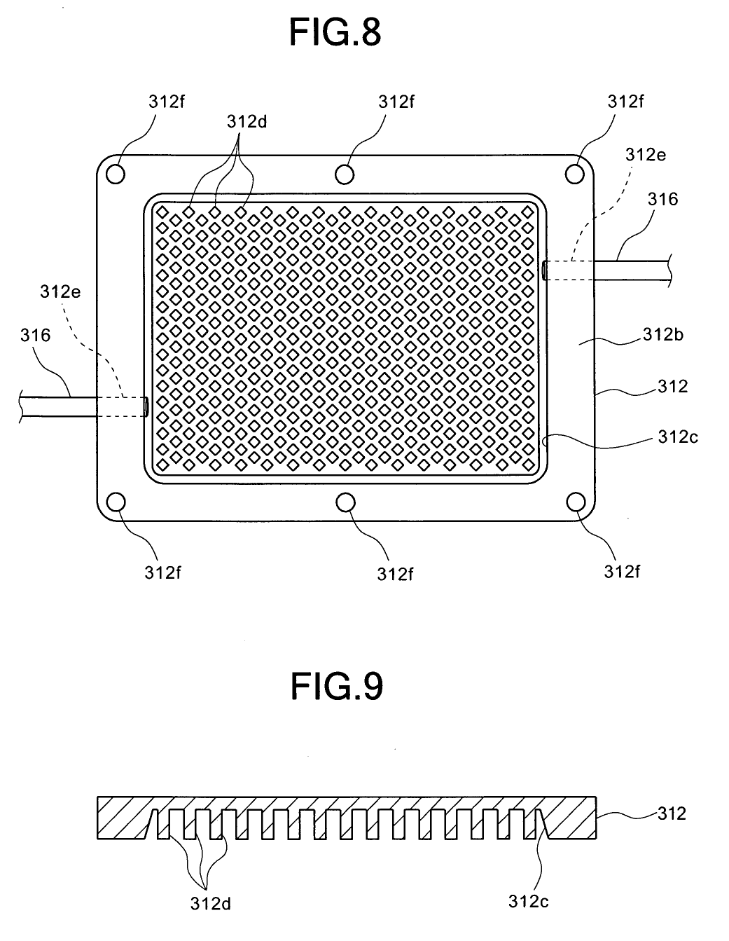

While the shape of each of the large number of protruding portions 112d has been a substantially circular truncated cone in the above described first and second preferred embodiments, a large number of substantially conical protruding portions 212d may be formed as shown in FIGS. 6 and 7, or a large number of substantially rectangular parallelepiped-shaped protruding portions 312d may be formed as shown in FIGS. 8 and 9. Furthermore, reference numbers in FIGS. 6 and 7 are shown by adding 200 to the reference numbers given to the same structural portions as those of the heat radiator 10 in the first preferred embodiment, and reference numbers in FIGS. 8 and 9 are shown by adding 300 to the reference numbers given to the same structural portions as those of the heat radiator 10 in the first preferred embodiment.

While the height of each of the large number of protruding portions 12d, 112d has been equal to the height of the peripheral portion surrounding the recessed portion 12c, 112c of the reverse 12b, 112b in the above described first and second preferred embodiments, it is not always that both are equal to each other. The height of each of the large number of protruding portions 12d, 112d is preferably greater than half of the depth of the recessed portions 12c, 112c.

While the pair of through holes 12e, 112e have been formed in the radiating member 12, 112 in the above described first and second preferred embodiments, it is not always required that the number of the through holes 12e, 112e is two. The radiating member may have at least one through hole for feeding a coolant into the heat radiator, and at least one through hole for discharging the coolant from the heat radiator.

In order to the heat sink characteristic of the heat radiator in the above described first and second preferred embodiments, the surface of the recessed portion 12c, 112c of the reverse 12b, 112b, and the surfaces of the large number of protruding portions 12d, 112d may be roughened to increase the surface areas thereof. In addition, in order to prevent the heat radiator from corroding with the coolant, the material of the heat radiator may be suitably selected from alloys having a high corrosion resistance, and the surfaces may be processed by alumite or nickel plating.

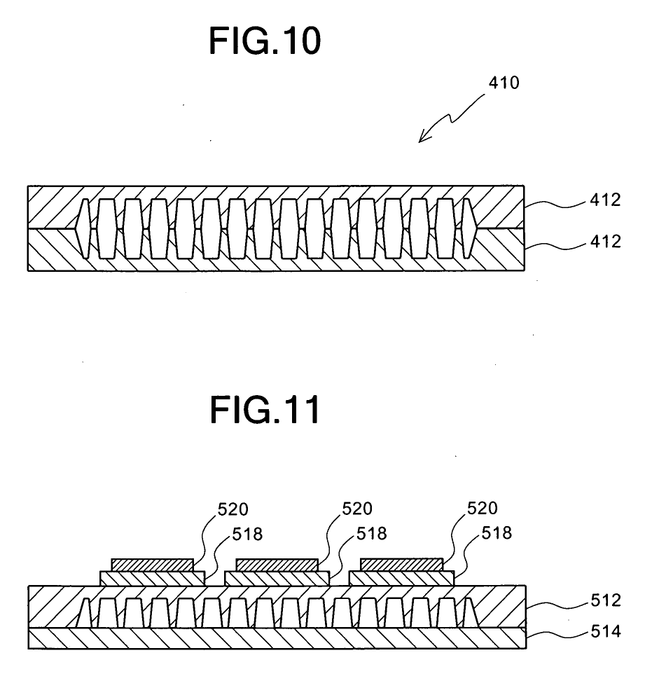

While the lid member 14, 114 has been mounted on the radiating member 12, 112 in the above described first and second preferred embodiments, the radiating member 412 may be combined with another radiating member 412 in place of the lid member 14, 114, as shown in FIG. 10. Furthermore, reference numbers in FIG. 10 are shown by adding 400 to the reference numbers given to the same structural portions as those of the heat radiator 10 in the first preferred embodiment.

The heat radiator in the above described first and second preferred embodiments may be bonded to be integrated with a part required for radiating heat from a heating element to a coolant, such as a metal/ceramic bonding substrate on which semiconductor chips and so fourth are mounted.

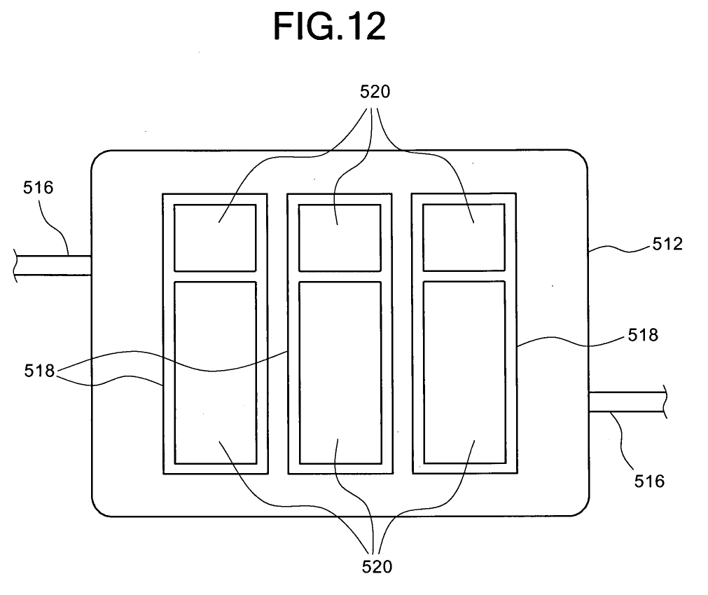

For example, as shown in FIGS. 11 and 12, metal/ceramic bonding substrates wherein a metal circuit plate 520 is bonded to each of a plurality of ceramic substrates 518 (or at least one ceramic substrate although three ceramic substrates 518 are shown) may be bonded to be integrated with a heat radiator, by bonding the ceramic substrates 518 to the top face of the radiating member 512 and by bonding the metal circuit plate 520 to the top face of each of the ceramic substrates 518. Furthermore, reference numbers in FIGS. 11 and 12 are shown by adding 500 to the reference numbers given to the same structural portions as those of the heat radiator 10 in the first preferred embodiment.

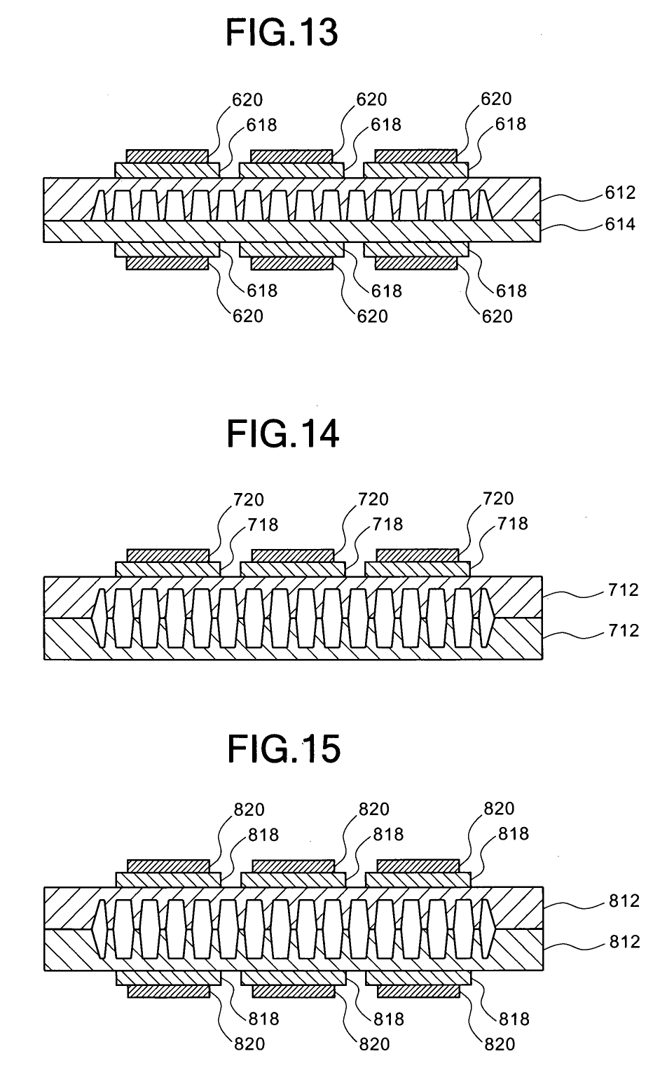

As shown in FIG. 13, metal/ceramic bonding substrates wherein a metal circuit plate 620 is bonded to each of a plurality of ceramic substrates 618 (or at least one ceramic substrate although three ceramic substrates 618 are shown) may be bonded to be integrated with a heat radiator, by bonding the ceramic substrates 618 to the top face of the radiating member 612 and the bottom face of the lid member 614 and by bonding the metal circuit plate 620 to each of the ceramic substrates 618. Furthermore, reference numbers in FIG. 13 are shown by adding 600 to the reference numbers given to the same structural portions as those of the heat radiator 10 in the first preferred embodiment.

As shown in FIG. 14, metal/ceramic bonding substrates wherein a metal circuit plate 720 is bonded to each of a plurality of ceramic substrates 718 (or at least one ceramic substrate although three ceramic substrates 718 are shown) may be bonded to be integrated with a heat radiator, by bonding the ceramic substrates 718 to the top face of the upper radiating member 712 combined with another radiating member 712 and by bonding the metal circuit plate 720 to the top face of each of the ceramic substrates 718. Furthermore, reference numbers in FIG. 14 are shown by adding 700 to the reference numbers given to the same structural portions as those of the heat radiator 10 in the first preferred embodiment.

As shown in FIG. 15, metal/ceramic bonding substrates wherein a metal circuit plate 820 is bonded to each of a plurality of ceramic substrates 818 (or at least one ceramic substrate although three ceramic substrates 818 are shown) may be bonded to be integrated with a heat radiator, by bonding the ceramic substrates 818 to the top face of the upper radiating member 812 and the bottom face of the lower radiating member 812 combined with the upper radiating member 812 and by bonding the metal circuit plate 820 to each of the ceramic substrates 818. Furthermore, reference numbers in FIG. 15 are shown by adding 800 to the reference numbers given to the same structural portions as those of the heat radiator 10 in the first preferred embodiment.

In the above described first and second preferred embodiments, the radiating member 12, 112 and the lid member 14 may be produced by machining or casting.

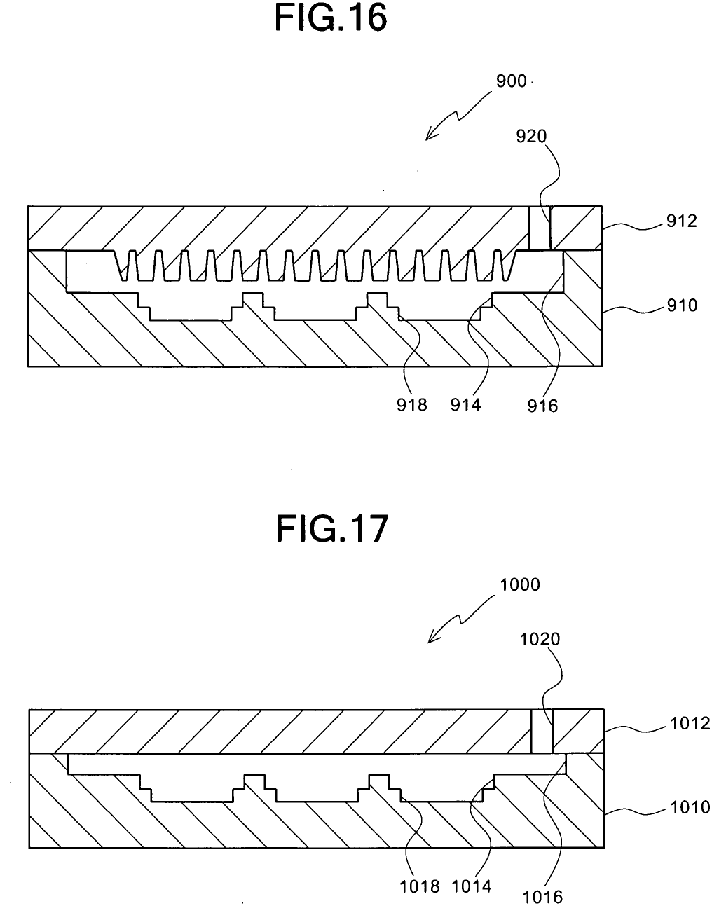

For example, the radiating members 512, 612, 712, 812, to which metal/ceramic bonding substrates are bonded as shown in FIGS. 11 through 15, may be produced by a method (the so-called molten metal bonding method) for solidifying a molten metal of aluminum or an aluminum alloy injected into a mold 900 in which a cavity 916 having a shape corresponding to a radiating member and a cavity 918 having a shape corresponding to a metal circuit plate are formed on both sides of a cavity 914 for housing therein a ceramic substrate as shown in FIG. 16. Furthermore, the mold 900 comprises a lower mold member 910 and an upper mold member 912 which has an inlet 920 for injecting a molten metal into the mold.

The lid member 614, to which metal/ceramic bonding substrates are bonded as shown in FIG. 13, may be produced a method (the so-called molten metal bonding method) for solidifying a molten metal of aluminum or an aluminum alloy injected into a mold 1000 in which a cavity 1016 having a shape corresponding to a lid member and a cavity 1018 having a shape corresponding to a metal circuit plate are formed on both sides of a cavity 1014 for housing therein a ceramic substrate as shown in FIG. 17. Furthermore, the mold 1000 comprises a lower mold member 1010 and an upper mold member 1012 which has an inlet 1020 for injecting a molten metal into the mold.

If the radiating member having the large number of protruding portions as the radiating member in the above described first and second preferred embodiments is produced by a typical molten metal bonding method, there are some cases where it is difficult to form protruding portions having a desired shape. In such cases, it is possible to form protruding portions having a desired shape by pressurizing a molten metal from the inlet of the mold by gas or the like after the molten metal is injected into the mold.

While the radiating member 12, 112 and the lid member 14, or the radiating member 12, 112 and another radiating member 12, 112 have been fixed to each other by means of screws in the above described first and second preferred embodiments, these members may be fixed to each other by soldering or clamping. Furthermore, these members are preferably fixed to each other via a sealing member, such as an O-ring or packing.

While the present invention has been disclosed in terms of the preferred embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A heat radiator comprising:
a metal body having an internal cavity which is formed therein and which has facing two inside surfaces, said metal body having a through hole for establishing a communication between the internal cavity and the outside; and
a large number of pillar portions which extend between the facing two inside surfaces and which are arranged at intervals.

2. A heat radiator as set forth in claim 1, wherein said metal body comprises:
a first member having said large number of pillar portions which are integrated therewith; and
a second member which is fixed to the first member for defining said internal cavity.

3. A heat radiator as set forth in claim 1, wherein said metal body comprises:
a first member which has a recessed portion in one side thereof and which has said large number of pillar portions integrated with a bottom face of the recessed portion; and
a second member which contacts a tip end of each of said large number of pillar portions of said first member.

4. A heat radiator as set forth in claim 1, wherein each of said large number of pillar portions has a shape of substantially circular truncated cone, substantially circular cone or substantially rectangular parallelepiped.

5. A heat radiator as set forth in claim 1, wherein said metal body is made of aluminum or an aluminum alloy.

6. A metal/ceramic bonding substrate with heat radiator, which comprises:
a ceramic substrate; and
a metal circuit plate bonded to one side of the ceramic substrate,
wherein a heat radiator as set forth in claim 1 is bonded to the other side of the ceramic substrate.
